(19) United States
(12) Patent Application Publication
(10) Pub. No.: US 2012/0243281 A1
(43) Pub. Date: Sep. 27, 2012

(54) POWER SEMICONDUCTOR DEVICE

(75) Inventor: Eitaro MIYAKE, Hyogo-ken (JP)

(73) Assignee: Kabushiki Kaisha Toshiba, Tokyo (JP)

(21) Appl. No.: 13/423,136

(22) Filed: Mar. 16, 2012

(30) Foreign Application Priority Data
Mar. 23, 2011 (JP) 2011-063706

(51) Int. Cl. H01L 23/495; H01L 27/06; H02M 7/5387

(52) U.S. Cl. 363/132; 257/675; 257/140; 257/E27.016; 257/E23.051

(57) ABSTRACT

According to one embodiment, a power semiconductor device includes a first conductor, a second conductor, and a first semiconductor chip. The first conductor includes a first portion and a second portion. The first portion includes a first major surface and a second major surface opposite thereto. The second portion includes a third major surface intersecting at right angles with the first major surface and a fourth major surface opposite to the third major surface. The fourth major surface becomes farther from the third major surface to become continuous with the second major surface with proximity to the first major surface. The second conductor includes a third portion and a fourth portion. The third portion is similar to the first portion. The fourth portion is similar to the second portion. The first semiconductor chip is placed between the second portion and the forth portion.

### CROSS-REFERENCE TO RELATED APPLICATION

This application is based upon and claims the benefit of priority from the prior Japanese Patent Application No. 2011-063706, filed on Mar. 23, 2011; the entire contents of which are incorporated herein by reference.

### FIELD

Embodiments described herein relate generally to a power semiconductor device used in an inverter device.

### BACKGROUND

Power semiconductor devices are used in inverter devices for motor drives of electric vehicles, air conditioners, and the like. Structures with high heat radiation properties are required for these power semiconductor devices in order to reduce the influence of heat generation due to a large current. As an example, there is a power semiconductor device having a structure in which a semiconductor element is placed between two conductors provided on a heat radiation plate. In the power semiconductor device, since heat is radiated from both the front surface and the back surface of the semiconductor element to the heat radiation plate via the conductors, heat radiation properties are improved. However, further reduction of size, weight, and price is required for these power semiconductor devices.

### BRIEF DESCRIPTION OF THE DRAWINGS

FIG. 1 is a circuit diagram of a three-phase inverter device 100 according to a first embodiment.

FIG. 2 is a perspective view of a main portion of a power semiconductor device according to the first embodiment.

FIG. 3 is a cross-sectional view of a main portion taken along line A-A of the perspective view of FIG. 2.

FIG. 4A and FIG. 4B are cross-sectional views of a main portion of an extrusion processing.

FIG. 5 is a cross-sectional view of a main portion of an drawing processing.

FIG. 6 is a cross-sectional view of a main portion for describing heat radiation characteristics of a power semiconductor device according to the first embodiment.

FIG. 7 is a cross-sectional view of a main portion for describing heat radiation characteristics of a power semiconductor device 111 of a Comparative Example 1.

FIG. 8 is a cross-sectional view of a main portion for describing heat radiation characteristics of a power semiconductor device 121 of a Comparative Example 2.

FIG. 9 is a circuit diagram of the three-phase inverter device 200 according to a second embodiment.

FIG. 10 is a perspective view of a main portion of a power semiconductor device 201 used for a three-phase inverter device 200 according to a second embodiment.

FIG. 11 is a cross-sectional view of a main portion taken along line B-B of the perspective view of FIG. 10.

### DETAILED DESCRIPTION

According to one embodiment, a power semiconductor device includes a first conductor, a second conductor, a first semiconductor chip, a heat radiation plate, and a resin. The first conductor includes a first portion and a second portion. The first portion includes a first major surface and a second major surface on an opposite side to the first major surface. The second portion includes a third major surface intersecting at right angles with the first major surface and a fourth major surface existing on an opposite side to the third major surface. The fourth major surface becomes farther from the third major surface to become continuous with the second major surface with proximity to the first major surface. The second conductor includes a third portion and a fourth portion. The third portion includes a fifth major surface and a sixth major surface on an opposite side to the fifth major surface. The fourth portion includes a seventh major surface intersecting at right angles with the fifth major surface and an eighth major surface existing on an opposite side to the seventh major surface. The eighth major surface becomes farther from the seventh major surface to become continuous with the sixth major surface with proximity to the fifth major surface. The first semiconductor chip includes a first electrode at a back surface and a second electrode at a front surface. The first electrode is electrically connected to the third major surface of the first conductor. The second electrode is electrically connected to the seventh major surface of the second conductor. The first chip is placed between the third major surface and the seventh major surface and configured to allow a current to flow between the first electrode and the second electrode. The heat radiation plate is joined to the first major surface of the first conductor and the fifth major surface of the second conductor via an insulating sheet. The resin seals the first conductor and the second conductor.

Hereinbelow, embodiments of the invention are described with reference to the drawings. The drawings used in the description of the embodiments are schematic for easier description; and in the actual practice, the configurations, dimensions, magnitude relationships, and the like of the components in the drawings are not necessarily the same as those illustrated in the drawings and may be appropriately altered to the extent that the effect of the invention is obtained.

### First Embodiment

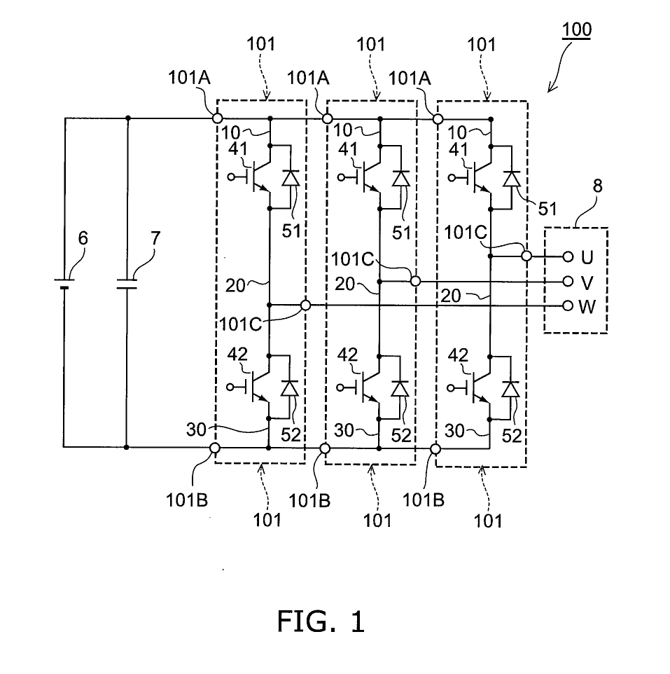

FIG. 1 is a circuit diagram of a three-phase inverter device 100 according to a first embodiment. The three-phase inverter device 100 includes a direct-current power source 6, a capacitor 7, three power semiconductor devices 101 that output alternating-current power of the U phase, the V phase, and the W phase, respectively, and an output unit 8. Both ends of the capacitor 7 are connected to both ends of the direct-current power source. The power semiconductor device 101 includes a positive electrode terminal 101A, a negative electrode terminal 101B, and an output terminal 101C. The positive electrode terminal 101A of each of the three power semiconductor devices 101 is connected to the positive electrode side of the direct-current power source, and the negative electrode terminal 101B thereof is connected to the negative electrode side of the direct-current power source. The output terminal 101C thereof is connected to the output unit 8.

The power semiconductor device 101 includes a high-side IGBT (insulated gate bipolar transistor) 41, a high-side diode 51, a low-side IGBT 42, and a low-side diode 52. The collector electrode of the high-side IGBT is connected to the positive electrode terminal 101A of the power semiconductor device 101, and the emitter electrode is connected to the collector electrode of the low-side IGBT 42. The cathode electrode and the anode electrode of the high-side diode 51 are connected to the collector electrode and the emitter electrode of the high-side IGBT 41, respectively. The emitter electrode of the low-side IGBT 42 is connected to the negative electrode terminal 101B of the power semiconductor device 101. The cathode electrode and the anode electrode of the low-side diode 52 are connected to the collector electrode and the emitter electrode of the low-side IGBT 42, respectively. The connection portion between the emitter electrode of the high-side IGBT 41 and the collector electrode of the low-side IGBT 42 is connected to the output terminal 101C of the power semiconductor device 101. The output terminal 101C of the power semiconductor device 101 of each phase is connected to the output unit 8 of each of the U phase, the V phase, and the W phase. A three-phase alternating current is outputted from the output unit 8 of the three-phase inverter device 100.

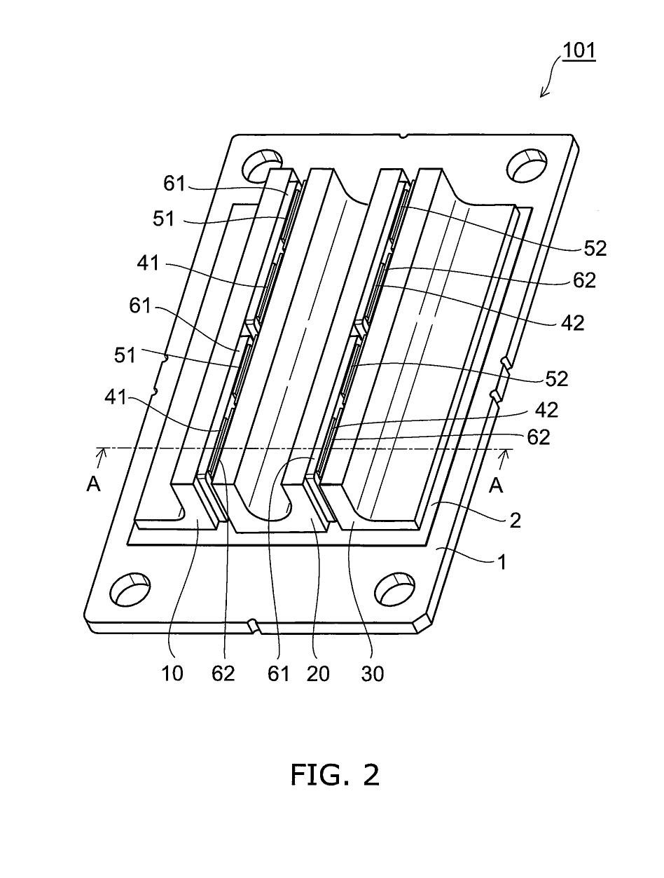

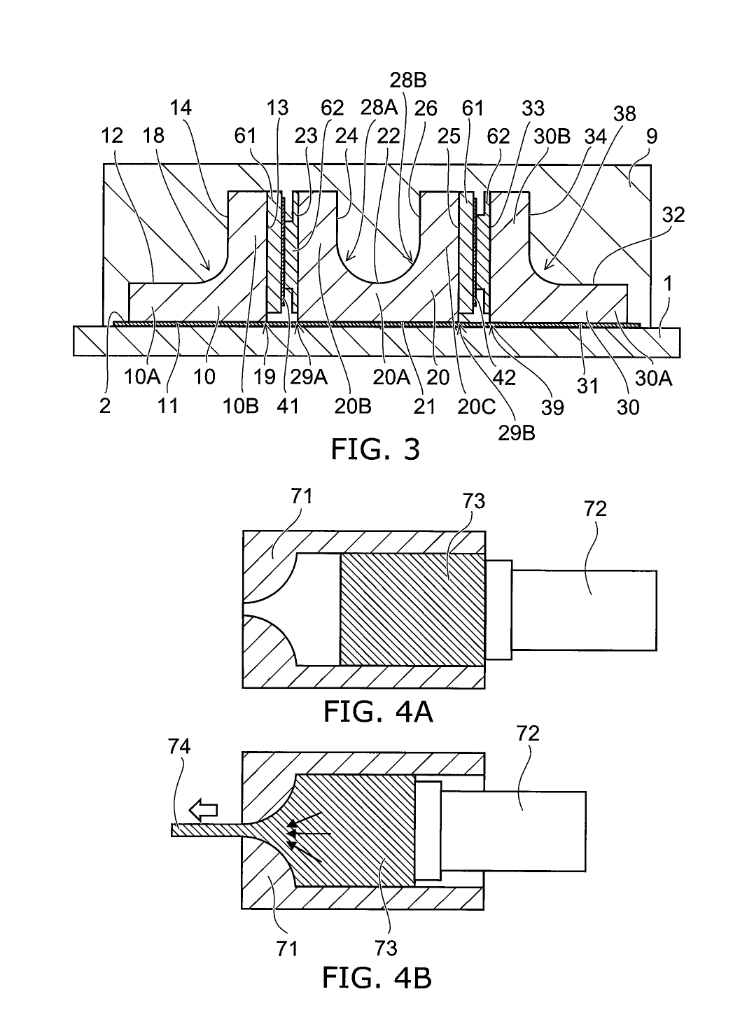

FIG. 2 is a perspective view of a main portion of an example of the power semiconductor device 101 mentioned above according to the embodiment. FIG. 2 is a view in which the illustration of a resin is omitted. FIG. 3 is a cross-sectional view of a main portion taken along line A-A of the perspective view of FIG. 2. As shown in FIG. 2 and FIG. 3, the power semiconductor device 101 according to the embodiment includes a first conductor 10, a second conductor 20, a third conductor 30, the high-side IGBT 41, the high-side diode 51, the low-side IGBT 42, the low-side diode 52, a heat radiation plate, and a resin.

The first conductor 10 includes a first portion 10A and a second portion 10B. The first portion 10A includes a first major surface 11 and a second major surface 12 on the opposite side to the first major surface 11. The second portion 10B includes a third major surface 13 intersecting at right angles with the first major surface 11 and a fourth major surface 14 that exists on the opposite side to the third major surface 13. The fourth major surface 14 becomes farther from the third major surface 13 to become continuous with the second major surface 12 with proximity to the first major surface 11. A portion 18 where the fourth major surface 14 becomes farther from the third major surface 13 to become continuous with the second major surface 12 with proximity to the first major surface 11 (hereinafter an “inner corner portion of the first conductor”) includes a surface convex toward a portion 19 where the first major surface 11 and the third major surface 13 intersect at right angles (hereinafter an “outer corner portion of the first conductor”).

That is, the first conductor 10 has a configuration in which an L-shaped trench is formed at one corner of a quadrangular prism. The side wall of the L-shaped trench corresponds to the fourth major surface 14 of the second portion 10B mentioned above. The bottom of the L-shaped trench corresponds to the second major surface 12 of the first portion 10A mentioned above. Although in the embodiment the inner corner portion 18 of the first conductor 10 has a cross-sectional shape of a quarter circular arc as an example, the cross-sectional shape may be other shapes as a matter of course to the extent that it is a smoothly bent shape. For example, the inner corner portion of the first conductor may be a plane having a linear cross-sectional shape and extending from the fourth major surface to the second major surface.

The second conductor 20 includes a third portion 20A, a fourth portion 20B, and a fifth portion 20C. The third portion 20A includes a fifth major surface 21 and a sixth major surface 22 on the opposite side to the fifth major surface. The fourth portion 20B includes a seventh major surface 23 intersecting at right angles with the fifth major surface 21 and an eighth major surface 24 that exists on the opposite side to the seventh major surface 23. The eighth major surface 24 becomes farther from the seventh major surface 23 to become continuous with the sixth major surface 22 with proximity to the fifth major surface 21. A portion 28A where the eighth major surface 24 becomes farther from the seventh major surface 23 to become continuous with the sixth major surface 22 with proximity to the fifth major surface 21 (an inner corner portion of the second conductor on one side) includes a surface convex toward a portion 29A where the fifth major surface 21 and the seventh major surface 23 intersect at right angles (an outer corner portion of the second conductor on the one side), similarly to the first conductor 10. The fifth portion 20C includes a ninth major surface 25 intersecting at right angles with the fifth major surface 21 and a tenth major surface 26 that exists on the opposite side to the ninth major surface 25. The tenth major surface 26 becomes farther from the ninth major surface 25 to become continuous with the sixth major surface 22 with proximity to the fifth major surface 21. A portion 28B where the tenth major surface becomes farther from the ninth major surface 25 to become continuous with the sixth major surface 22 with proximity to the fifth major surface 21 (an inner corner portion of the second conductor on the other side) includes a surface convex toward a portion 29B where the fifth major surface 21 and the ninth major surface 25 intersect at right angles (an outer corner portion of the second conductor on the other side), similarly to the first conductor.

That is, the second conductor 20 has a configuration in which a U-shaped trench extending inward from one major surface of a quadrangular prism is formed. The side walls of the U-shaped trench correspond to the eighth major surface 24 of the fourth portion mentioned above and the tenth major surface 26 of the fifth portion mentioned above, respectively. The bottom of the U-shaped trench corresponds to the sixth major surface 22 of the third portion 20A mentioned above. In the embodiment, since the cross-sectional shape of the portion around the U-shaped bottom is a nearly semicircular shape, the sixth major surface 22 is difficult to recognize as a plane. In such a case, it is assumed that the sixth major surface is a plane parallel to the fifth major surface which is formed at the bottom of the U-shaped trench mentioned above and has an area of nearly zero. In the case where the spacing between the fourth portion 20B and the fifth portion 20C of the second conductor 20 (the spacing between the inner corner portions 28A and 28B of the second conductor) is wider than that of the embodiment, the sixth major surface may be a plane parallel to the fifth major surface and having a visually recognizable area, depending on the design of the power semiconductor device 101. Although in the embodiment the inner corner portions 28A and 28B of the second conductor have a cross-sectional shape of a quarter circular arc as an example, the cross-sectional shape may be other shapes as a matter of course to the extent that it is a smoothly bent shape. For example, the inner corner portions 28A and 28B of the second conductor may be a plane having a linear cross-sectional shape and extending from the eighth major surface (or the tenth major surface) to the sixth major surface.

The high-side IGBT chip 41 (a first semiconductor chip) includes a collector electrode (a first electrode) at the back surface and an emitter electrode (a second electrode) and a gate electrode at the front surface (details of the electrodes not shown). The collector electrode is electrically connected to the third major surface 13 of the first conductor 10 via a conductive plate 61 made of aluminum, copper, or the like. The emitter electrode is electrically connected to the seventh major surface 23 of the second conductor 20 via a conductive plate 62 made of aluminum, copper, or the like and having a protrusion on the emitter electrode side. The electrode and the conductive plate 61 or 62 are bonded by a not-shown solder, and the conductive plate 61 or 62 and the first conductor 10 or the second conductor 20 are bonded by a not-shown solder. Although in the embodiment the first conductor or the second conductor is electrically connected to each electrode of the high-side IGBT chip 41 via the conductive plate 61 or 62, they may be electrically connected in a direct manner by a solder as a matter of course. The gate electrode is insulated from the emitter electrode and the second conductor 20, and is electrically connected to the gate terminal of the power semiconductor device 101 (details not shown). In the embodiment, the high-side IGBT chip 41 is a structure in which two IGBTs 41 are electrically connected in parallel. A plurality of IGBTs 41 are connected in parallel in accordance with the capacity of the current of the power semiconductor device 101.

The high-side diode 51 (it is also possible to take this as the first semiconductor chip) is electrically connected in parallel to the high-side IGBT 41. That is, the cathode electrode of the high-side diode 51 is connected to the collector electrode of the high-side IGBT 41, and the anode electrode of the high-side diode 51 is connected to the emitter electrode of the high-side IGBT 41 (details not shown). The high-side diode 51 is electrically connected in parallel to each of the plurality of high-side IGBTs 41. The high-side diode 51 is preferably an FRD (fast recovery diode) excellent in switching characteristics. The high-side IGBT 41 and the high-side diode 51 constitute a high-side switch of each phase of the three-phase inverter device 100.

The third conductor 30 includes a sixth portion 30A and a seventh portion 30B. The sixth portion 30A includes an eleventh major surface 31 and a twelfth major surface 32 on the opposite side to the eleventh major surface 31. The seventh portion 30B includes a thirteenth major surface 33 intersecting at right angles with the eleventh major surface 31 and a fourteenth major surface 34 that exists on the opposite side to the thirteenth major surface 33. The fourteenth major surface 34 becomes farther from the thirteenth major surface 33 to become continuous with the twelfth major surface 32 with proximity to the eleventh major surface 31. A portion 38 where the fourteenth major surface 34 becomes farther from the thirteenth major surface 33 to become continuous with the twelfth major surface 32 with proximity to the eleventh major surface 31 (hereinafter an “inner corner portion of the third conductor”) includes a surface convex toward a portion 39 where the eleventh major surface 31 and the thirteenth major surface 33 intersect at right angles (hereinafter an “outer corner portion of the third conductor”).

That is, the third conductor 30 has a configuration in which an L-shaped trench is formed at one corner of a quadrangular prism. The side wall of the L-shaped trench corresponds to the fourteenth major surface 34 of the seventh portion mentioned above. The bottom of the L-shaped trench corresponds to the twelfth major surface 32 of the sixth portion mentioned above. Although in the embodiment the inner corner portion 38 of the third conductor 30 has a cross-sectional shape of a quarter circular arc as an example, the cross-sectional shape may be other shapes as a matter of course to the extent that is it a smoothly bent shape. For example, the inner corner portion 38 of the third conductor 30 may be a plane having a linear cross-sectional shape and extending from the fourteenth major surface 34 to the twelfth major surface 32.

The low-side IGBT chip 42 (a second semiconductor chip) includes a collector electrode (a third electrode) at the back surface and an emitter electrode (a fourth electrode) and a gate electrode at the front surface (details of the electrodes not shown). The collector electrode is electrically connected to the tenth major surface 25 of the second conductor 20 via a conductive plate 61 made of aluminum, copper, or the like. The emitter electrode is electrically connected to the thirteenth major surface 33 of the third conductor 30 via a conductive plate 62 made of aluminum, copper, or the like and having a protrusion on the emitter electrode side. The electrode and the conductive plate 61 or 62 are bonded by a not-shown solder, and the conductive plate 61 or 62 and the second conductor 20 or the third conductor 30 are bonded by a not-shown solder. Although in the embodiment the second conductor or the third conductor is electrically connected to each electrode of the low-side IGBT chip 42 via the conductive plate 61 or 62, they may be electrically connected in a direct manner by a solder as a matter of course. The gate electrode is insulated from the emitter electrode and the third conductor 30, and is electrically connected to the gate terminal of the power semiconductor device 101 (details not shown). In the embodiment, the low-side IGBT chip 42 is a structure in which two IGBTs 42 are electrically connected in parallel. A plurality of IGBTs 42 are connected in parallel in accordance with the capacity of the current of the power semiconductor device 101.

The low-side diode 52 (it is also possible to take this as the second semiconductor chip) is electrically connected in parallel to the low-side IGBT 42. That is, the cathode electrode of the low-side diode 52 is connected to the collector electrode of the low-side IGBT 42, and the anode electrode of the low-side diode 52 is connected to the emitter electrode of the low-side IGBT 42 (details not shown). The low-side diode 52 is electrically connected in parallel to each of the plurality of low-side IGBTs 42. The low-side diode 52 is preferably an FRD (fast recovery diode) excellent in switching characteristics. The low-side IGBT 42 and the low-side diode 52 constitute a low-side switch of each phase of the three-phase inverter device 100.

A heat radiation plate 1 is joined to the first major surface 11 of the first conductor 10, the fifth major surface 21 of the second conductor 20, and the eleventh major surface 31 of the third conductor 30 via an insulating sheet 2. A resin 9 is formed on the heat radiation plate 1, and seals the first conductor 10, the second conductor 20, and the third conductor 30 and the high-side IGBT chip 41, the high-side diode 51, the low-side IGBT chip 42, and the low-side diode 52. The positive electrode terminal 101A, the negative electrode terminal 101B, the gate electrode terminal, and the output terminal 101C not shown are provided outside the resin 9. The first conductor 10 is electrically connected to the positive electrode terminal 101A, and the third conductor 30 is electrically connected to the negative electrode terminal 101B. The second conductor 20 is electrically connected to the output terminal 101C. The gate electrode of each of the high-side IGBT 41 and the low-side IGBT 42 is connected to the gate electrode terminal of the power semiconductor device 101, and is connected to an external controller.

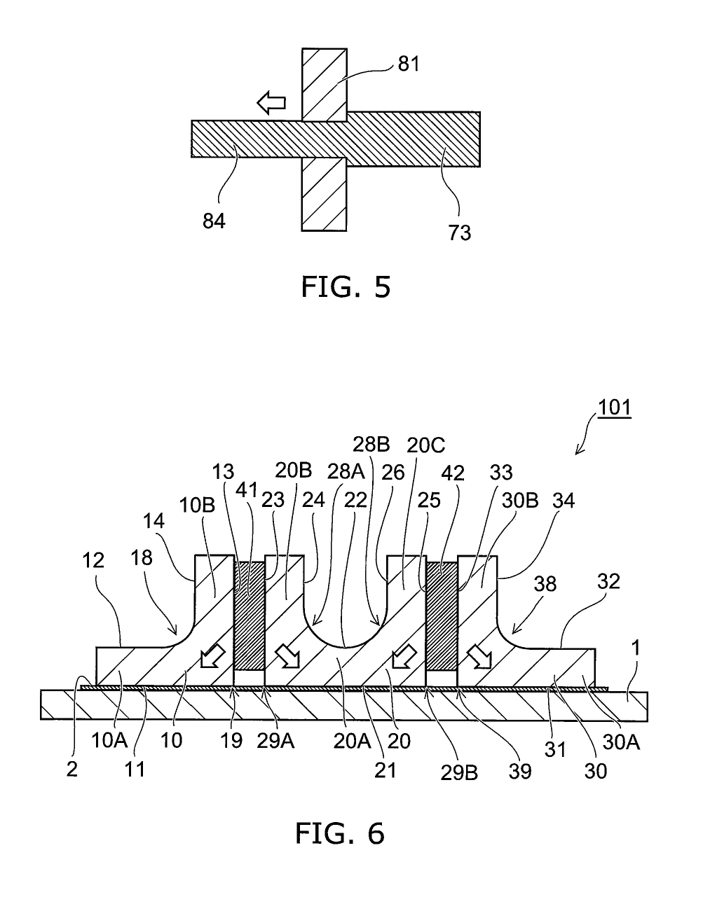

Here, the first conductor 10, the second conductor 20, and the third conductor 30 are made of a metal material such as copper or aluminum. The conductors are formed by the extrusion processing shown in FIG. 4 or the drawing processing shown in FIG. 5. In the extrusion processing shown in FIG. 4, a copper material 73 that is the material of the conductor is put in a die 71 having an opening with a shape identical to the cross-sectional shape of each conductor, and the copper material 73 is extruded using a die 72 for extrusion. Thereby, each conductor is extruded from the opening, and a conductor having a cross-sectional shape identical to the shape of the opening is obtained. In the drawing processing shown in FIG. 5, a die 81 having an opening with a shape identical to the cross-sectional shape of each conductor is pressed against a copper material, and the copper material is drawn through the opening. Thereby, a conductor having a cross-sectional shape identical to the shape of the opening is obtained.

In both of the extrusion processing and the drawing processing, the shape of the opening of the die does not necessarily need to be identical to the cross-sectional shape of each conductor. Additional processing such as cutting may be performed on each conductor after both processings; thereby, the cross-sectional shape of each conductor can be made into a desired cross-sectional shape. The conductor mentioned above can be formed not only by performing either extrusion processing or drawing processing singly, but also by performing extrusion processing and drawing processing in combination each one or more times. For example, both extrusion processing and drawing processing may be performed for rough fashioning, and then drawing processing may be performed for the finishing processing. In this case, the shape of the opening of the die used for the final finishing drawing processing and the cross-sectional shape of the conductor processed are almost the same shape.

These processing methods for a conductor are less costly in processing terms and can suppress an increase in manufacturing costs as compared to other processing methods such as cutting. Furthermore, the extrusion processing or the drawing processing mentioned above has the advantage that the inner corner portions 18, 28A, 28B, and 38 of the conductors are easily formed into curved shapes as shown in the cross-sectional view of FIG. 3 while the perpendicular shapes of the outer corner portions 19, 29A, 29B, and 39 of the conductors are provided, as compared to a method in which the first to third conductors are fashioned by attaching pieces of copper material together.

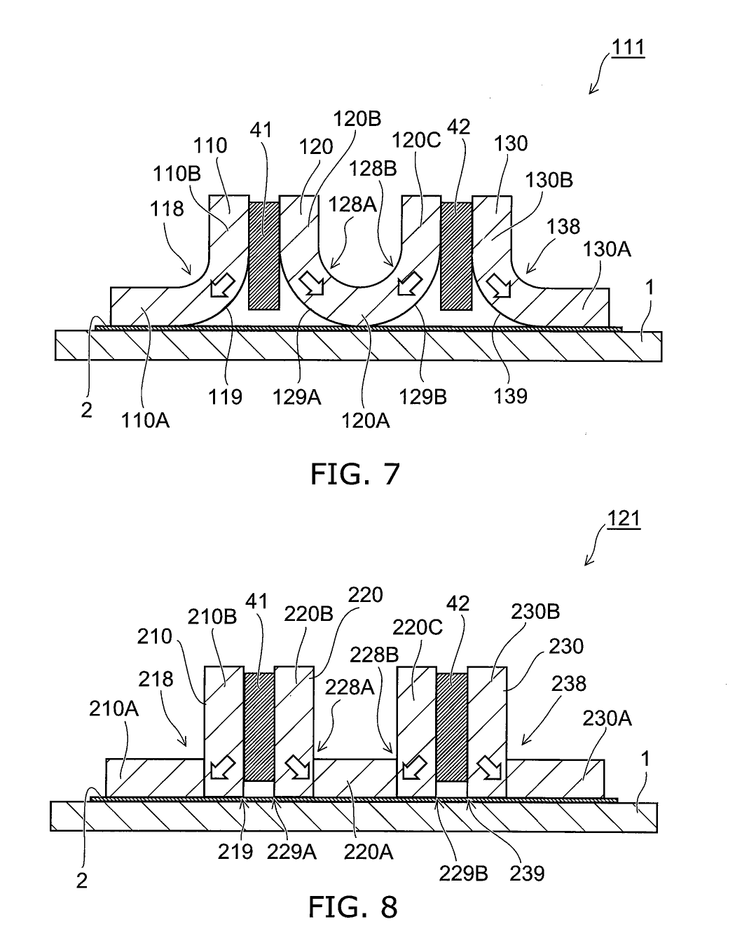

Next, the heat radiation characteristics in the operation of the power semiconductor device 101 according to the embodiment are described. FIG. 6 is a cross-sectional view of a main portion for describing the heat radiation characteristics of the power semiconductor device 101 according to the embodiment. FIG. 7 and FIG. 8 are cross-sectional views of main portions for describing the heat radiation characteristics of power semiconductor devices 111 and 121 of Comparative Example 1 and Comparative Example 2. As shown in FIG. 6, in the operation of the power semiconductor device 101 according to the embodiment, the heat generated by a current flowing through the high-side IGBT 41 or the low-side IGBT 42 is transmitted through the paths indicated by the arrows in the drawing and released to the heat radiation plate 1 via the first conductor, the second conductor, and the third conductor. Here, in the power semiconductor device 101 according to the embodiment, since the first to third conductors are conductors formed by extrusion processing or drawing processing as described above, the conductors have the curved shapes of the inner corner portions 18, 28A, 28B, and 38 while having the perpendicular shapes of the outer corner portions 19, 29A, 29B, and 39. Thereby, the power semiconductor device 101 according to the embodiment can ensure large cross-sectional areas between the inner corner portions 18, 28A, 28B, and 38 and the outer corner portions 19, 29A, 29B, and 39 of the conductors, respectively, as compared to the power semiconductor devices 111 and 121 of Comparative Example 1 and Comparative Example 2 described later. Furthermore, large contact areas between the conductors and the heat radiation plate can be ensured. As a result of these, heat radiation properties are improved.

In contrast, in the power semiconductor device 111 according to Comparative Example 1, as shown in FIG. 7, a first to a third conductor 110, 120, and 130 include outer corner portions 119, 129A, 129B, and 139 and inner corner portions 118, 128A, 128B, and 138 formed by bending a flat plate perpendicularly. The heat radiation paths from each IGBT in the operation of the power semiconductor device 111 are indicated by arrows similarly to the power semiconductor device 101 according to the embodiment of FIG. 6. For example, the first conductor 110 includes a first portion 110A and a second portion 110B formed by bending a flat plate almost perpendicularly at almost the center of the flat plate. The third major surface of the first conductor 110 is formed perpendicular to the first major surface, but does not intersect at right angles with the first major surface. That is, the cross section of the outer corner portion of the first conductor does not have a perpendicular shape but has a curved shape away from the heat radiation plate 1. This applies also to the second conductor and the third conductor. Therefore, the power semiconductor device 111 of Comparative Example 1 has a smaller cross-sectional area between the inner corner portion and the outer corner portion than the power semiconductor device 101 according to the embodiment. Furthermore, since the outer corner portions 119, 129A, 129B, and 139 of the conductors of the power semiconductor device 111 of Comparative Example 1 are not in a perpendicular shape but in a curved shape, for example, the contact area of the first portion 110A of the first conductor 110 with the heat radiation plate 1 is smaller than the contact area between the first portion 10A of the first conductor 10 and the heat radiation plate 1 of the power semiconductor device 101 according to the embodiment (this applies also to the second conductor and the third conductor). Consequently, the power semiconductor device 111 of Comparative Example 1 is inferior in heat radiation properties to the power semiconductor device 101 according to the embodiment.

In the power semiconductor device 121 of Comparative Example 2, as shown in FIG. 8, a first to a third conductor 210, 220, and 230 are formed by attaching one ends of separated flat plates together perpendicularly. The heat radiation paths from each IGBT in the operation of the power semiconductor device 121 are indicated by arrows similarly to the power semiconductor device 101 according to the embodiment of FIG. 6. For example, the first conductor 210 is formed by attaching one ends of first portions 210A and 210B of flat plates together such that the first portion 210A and the second portion 210B intersect at right angles. As a result, the outer corner portion 219 of the first conductor 210 has a perpendicular shape, and also the inner corner portion 218 has a perpendicular shape. By the outer corner portion 219 having a perpendicular shape, the contact area between the first portion 210A of the first conductor 210 and the heat radiation plate 1 of the power semiconductor device 121 of Comparative Example 2 is almost equal to the contact area between the first portion 10A of the first conductor 10 and the heat radiation plate 1 of the power semiconductor device 101 according to the embodiment. However, in the power semiconductor device 121 of Comparative Example 2, since the inner corner portion 218 of the first conductor 210 has a perpendicular shape, the cross-sectional area between the inner corner portion 218 and the outer corner portion 219 of the first conductor 210 is smaller than that of the embodiment. This applies also to the second conductor 220 and the third conductor 230. As a result, the power semiconductor device 121 of Comparative Example 2 is inferior in heat radiation properties to the power semiconductor device 101 according to the embodiment.

### Second Embodiment

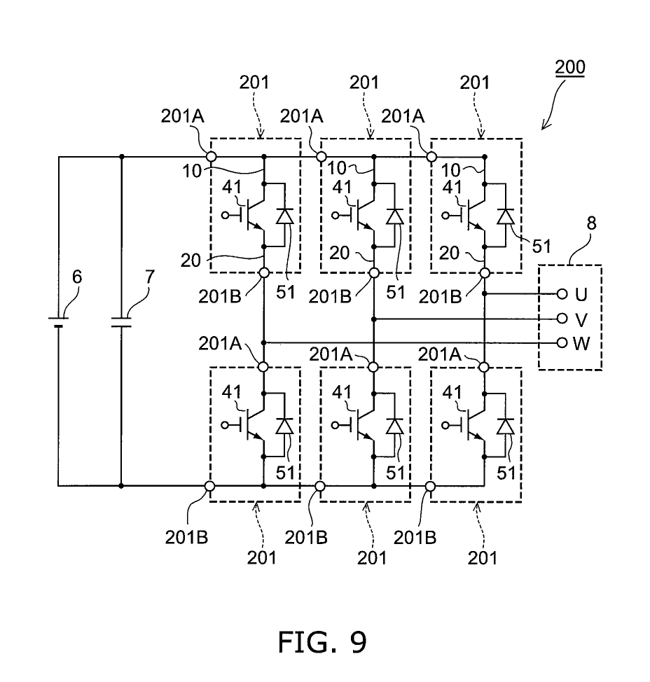

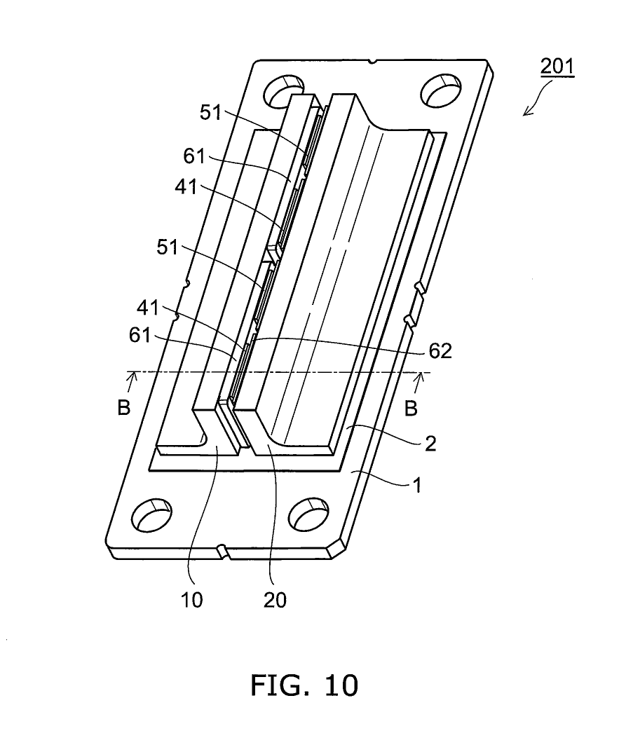

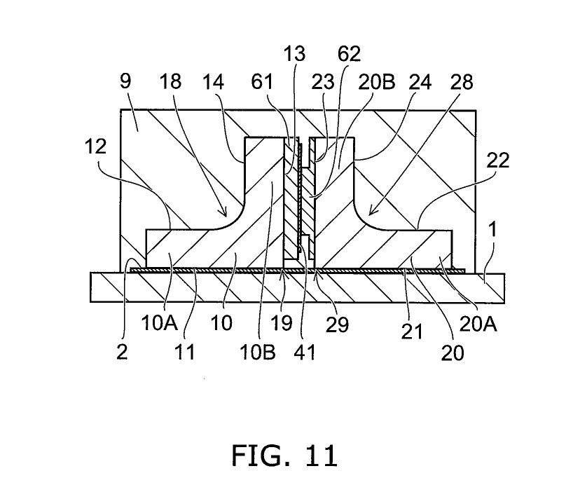

Next, a three-phase inverter device 200 and a power semiconductor device 201 used therefor according to a second embodiment are described using FIG. 9 to FIG. 11. FIG. 9 is a circuit diagram of the three-phase inverter device 200 according to the second embodiment. FIG. 10 is a perspective view of a main portion of the power semiconductor device 201 used for the three-phase inverter device 200 according to the embodiment. FIG. 10 is a view in which the illustration of a resin is omitted. FIG. 11 is a cross-sectional view of a main portion taken along line B-B of the perspective view of FIG. 10. Components with configurations identical to the configurations described in the first embodiment are indicated by the same reference numerals or symbols, and a description thereof is omitted. Differences from the first embodiment are mainly described.

The power semiconductor device 101 used for the three-phase inverter device 100 according to the first embodiment includes a high-side switch composed of the high-side IGBT 41 and the high-side diode 51 connected in parallel thereto and a low-side switch composed of the low-side IGBT 42 and the low-side diode 52 connected in parallel thereto in a resin. In contrast, the power semiconductor device 201 according to the embodiment includes either the high-side switch or the low-side switch mentioned above of each phase in a resin. That is, the power semiconductor device 201 according to the embodiment includes a positive electrode terminal 201A, a negative electrode terminal 201B, a gate electrode terminal (not shown), the IGBT 41, and the diode 51. The collector electrode of the IGBT 41 is electrically connected to the positive electrode terminal 201A, the emitter electrode is electrically connected to the negative electrode terminal 201B, and the gate electrode is electrically connected to the gate electrode terminal. The cathode electrode of the diode 51 is electrically connected to the collector electrode of the IGBT 41, and the anode electrode is electrically connected to the emitter electrode of the IGBT 41. Each phase of the three-phase inverter device 200 includes two power semiconductor devices 201 connected in series as the high-side switch and the low-side switch, respectively. The positive electrode terminal 201A of the high-side power semiconductor device 201 is electrically connected to the positive electrode side of the direct-current power source 6, and the negative electrode terminal 201B is electrically connected to the positive electrode terminal 201A of the low-side power semiconductor device 201. The negative electrode terminal 201B of the low-side power semiconductor device 201 is electrically connected to the negative electrode side of the direct-current power source 6. The negative electrode terminal 201B of the high-side power semiconductor device 201 is electrically connected to the output terminal 8 of each phase. Thus, the three-phase inverter device 200 according to the embodiment is composed of six power semiconductor devices 201, and the power semiconductor device 201 is composed of the IGBT 41 and the diode 51 of the high-side or the low-side of each phase. In this point, the three-phase inverter device 200 and the power semiconductor device 201 according to the embodiment are different from those of the first embodiment.

Next, the power semiconductor device 201 according to the embodiment is described in detail using FIG. 10 and FIG. 11. The power semiconductor device 201 according to the embodiment includes the first conductor 10, the second conductor 20, the IGBT 41, the diode 51, a heat radiation plate, and a resin. A description of identical or similar portions to the first embodiment is omitted.

The first conductor 10 includes the first portion 10A and the second portion 10B and has the same structure as the first embodiment; therefore, a description is omitted.

The second conductor 20 has the same structure as the left half of the second conductor 20 of the first embodiment in FIG. 2 or FIG. 3. That is, the second conductor has the following structure. The second conductor includes the third portion 20A and the fourth portion 20B. The third portion 20A includes the fifth major surface 21 and the sixth major surface 22 on the opposite side to the fifth major surface. The fourth portion 20B includes the seventh major surface 23 intersecting at right angles with the fifth major surface 21 and the eighth major surface 24 that exists on the opposite side to the seventh major surface 23. The eighth major surface becomes farther from the seventh major surface 23 to become continuous with the sixth major surface 22 with proximity to the fifth major surface 21. A portion 28 where the eighth major surface 24 becomes farther from the seventh major surface 23 to become continuous with the sixth major surface 22 with proximity to the fifth major surface 21 (an inner corner portion of the second conductor) includes a surface convex toward a portion 29 where the fifth major surface 21 and the seventh major surface 23 intersect at right angles (an outer corner portion of the second conductor), similarly to the first conductor 10.

That is, the second conductor 20 has a configuration in which an L-shaped trench is formed at one corner of a quadrangular prism in a position symmetrical to the first conductor 10. The side wall of the L-shaped trench corresponds to the eighth major surface 24 of the fourth portion mentioned above. The bottom of the L-shaped trench corresponds to the sixth major surface 22 of the third portion mentioned above. Although in the embodiment the inner corner portion 18 of the first conductor 10 and the inner corner portion 28 of the second conductor 20 have a cross-sectional shape of a quarter circular arc as an example, the cross-sectional shape may be other shapes as a matter of course to the extent that it is a smoothly bent shape, similarly to the first embodiment. For example, the inner corner portion 18 of the first conductor 10 and the inner corner portion 28 of the second conductor 20 may be planes having linear cross-sectional shapes and extending from the fourth major surface to the second major surface and extending from the eighth major surface to the sixth major surface, respectively.

The IGBT 41 and the diode 51 are provided between the first conductor 10 and the second conductor 20 similarly to the first embodiment. The heat radiation plate 1 is joined to the first major surface 11 of the first conductor 10 and the fifth major surface 21 of the second conductor 20 via the insulating sheet 2 similarly to the first embodiment. The resin 9 is formed on the heat radiation plate 1 and seals the first conductor 10, the second conductor 20, the IGBT chip 41, and the diode 51 similarly to the first embodiment. Otherwise, the three-phase inverter device 200 and the power semiconductor device 201 according to the embodiment have similar configurations to the three-phase inverter device 100 and the power semiconductor device 101 according to the first embodiment.

Also in the power semiconductor device 201 according to the embodiment, the first conductor and the second conductor are conductors formed by extrusion processing or drawing processing similarly to the power semiconductor device 101 according to the first embodiment, and therefore have the curved shapes of the inner corner portions while having the perpendicular shapes of the outer corner portions of the first conductor and the second conductor. Thereby, also the power semiconductor device 201 according to the embodiment can ensure large cross-sectional areas between the inner corner portions 18 and 28 and the outer corner portions 19 and 29 of the conductors, respectively, and can ensure large contact areas between the conductors and the heat radiation plate, similarly to the power semiconductor device according to the first embodiment. Therefore, heat radiation properties are improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power semiconductor device comprising:
a first conductor including a first portion and a second portion, the first portion including a first major surface and a second major surface on an opposite side to the first major surface, the second portion including a third major surface intersecting at right angles with the first major surface and a fourth major surface existing on an opposite side to the third major surface, and the forth major surface becoming farther from the third major surface to become continuous with the second major surface with proximity to the first major surface;
a second conductor including a third portion and a fourth portion, the third portion including a fifth major surface and a sixth major surface on an opposite side to the fifth major surface, the fourth portion including a seventh major surface intersecting at right angles with the fifth major surface and an eighth major surface existing on an opposite side to the seventh major surface, and the eighth major surface becoming farther from the seventh major surface to become continuous with the sixth major surface with proximity to the fifth major surface;
a first semiconductor chip including a first electrode electrically connected to the third major surface of the first conductor at a back surface, including a second electrode electrically connected to the seventh major surface of the second conductor at a front surface, placed between the third major surface and the seventh major surface, and configured to allow a current to flow between the first electrode and the second electrode;
a heat radiation plate joined to the first major surface of the first conductor and the fifth major surface of the second conductor via an insulating sheet; and
a resin sealing the first conductor and the second conductor.

2. The power semiconductor device according to claim 1, wherein each of the first conductor and the second conductor is formed by pressing a die having a prescribed opening against a conductive material and extruding or drawing the conductive material through the opening of the die.

3. The power semiconductor device according to claim 1, wherein the first semiconductor chip further includes a gate electrode that controls a current flowing between the first electrode and the second electrode at a front surface of the first semiconductor chip in a manner insulated from the second electrode.

4. The power semiconductor device according to claim 3, further comprising a diode including a cathode electrode electrically connected to the first electrode of the first semiconductor chip and an anode electrode electrically connected to the second electrode of the first semiconductor chip between the third major surface of the first conductor and the seventh major surface of the second conductor.

5. The power semiconductor device according to claim 1, wherein
a portion where the fourth major surface becomes farther from the third major surface to become continuous with the second major surface with proximity to the first major surface includes a surface convex toward a portion where the first major surface and the third major surface intersect at right angles and
a portion where the eighth major surface becomes farther from the seventh major surface to become continuous with the sixth major surface with proximity to the fifth major surface includes a surface convex toward a portion where the fifth major surface and the seventh major surface intersect at right angles.

6. The power semiconductor device according to claim 1, wherein
a portion where the fourth major surface becomes farther from the third major surface to become continuous with the second major surface with proximity to the first major surface includes a plane and
a portion where the eighth major surface becomes farther from the seventh major surface to become continuous with the sixth major surface with proximity to the fifth major surface includes a plane.

7. The power semiconductor devicer according to claim 1, wherein the first semiconductor chip is an IGBT.

8. The power semiconductor device according to claim 1, wherein
the second conductor further includes a fifth portion including a ninth major surface intersecting at right angles with the fifth major surface on an opposite side to the seventh major surface and a tenth major surface existing on an opposite side to the ninth major surface, the tenth major surface becoming farther from the ninth major surface to become continuous with the sixth major surface with proximity to the fifth major surface and
the power semiconductor device further comprises:
a third conductor including a sixth portion and a seventh portion, the sixth portion including an eleventh major surface joined to the heat radiation plate via the insulating sheet and a twelfth major surface on an opposite side to the eleventh major surface, the seventh portion including a thirteenth major surface intersecting at right angles with the eleventh major surface and a fourteenth major surface existing on an opposite side to the thirteenth major surface, and the fourteenth major surface becoming farther from the thirteenth major surface to become continuous with the twelfth major surface with proximity to the eleventh major surface; and
a second semiconductor chip including a third electrode electrically connected to the ninth major surface of the second conductor at a back surface, including a fourth electrode electrically connected to the thirteenth major surface of the third conductor at a front surface, placed between the ninth major surface and the thirteenth major surface, and configured to allow a current to flow between the third electrode and the fourth electrode.

9. The power semiconductor device according to claim 8, wherein each of the first conductor, the second conductor, and the third conductor is formed by pressing a die having a prescribed opening against a conductive material and extruding or drawing the conductive material through the opening of the die.

10. The power semiconductor device according to claim 8, wherein
the first semiconductor chip further includes a first gate electrode that controls a current flowing between the first electrode and the second electrode at a front surface of the first semiconductor chip in a manner insulated from the second electrode and
the second semiconductor chip further includes a second gate electrode that controls a current flowing between the third electrode and the fourth electrode at a front surface of the second semiconductor chip in a manner insulated from the fourth electrode.

11. The power semiconductor device according to claim 10, further comprising:
a first diode including a first cathode electrode electrically connected to the first electrode of the first semiconductor chip and a first anode electrode electrically connected to the second electrode of the first semiconductor chip between the third major surface of the first conductor and the seventh major surface of the second conductor; and
a second diode including a second cathode electrode electrically connected to the third electrode of the second semiconductor chip and a second anode electrode electrically connected to the fourth electrode of the second semiconductor chip between the ninth major surface of the second conductor and the thirteenth major surface of the third conductor.

12. The power semiconductor device according to claim 8, wherein
a portion where the fourth major surface becomes farther from the third major surface to become continuous with the second major surface with proximity to the first major surface includes a surface convex toward a portion where the first major surface and the third major surface intersect at right angles,
a portion where the eighth major surface becomes farther from the seventh major surface to become continuous with the sixth major surface with proximity to the fifth major surface includes a surface convex toward a portion where the fifth major surface and the seventh major surface intersect at right angles,
a portion where the tenth major surface becomes farther from the ninth major surface to become continuous with the sixth major surface with proximity to the fifth major surface includes a surface convex toward a portion where the fifth major surface and the ninth major surface intersect at right angles, and
a portion where the fourteenth major surface becomes farther from the thirteenth major surface to become continuous with the twelfth major surface with proximity to the eleventh major surface includes a surface convex toward a portion where the eleventh major surface and the thirteenth major surface intersect at right angles.

13. The power semiconductor device according to claim 8, wherein
a portion where the fourth major surface becomes farther from the third major surface to become continuous with the second major surface with proximity to the first major surface includes a plane,
a portion where the eighth major surface becomes farther from the seventh major surface to become continuous with the sixth major surface with proximity to the fifth major surface includes a plane,
a portion where the tenth major surface becomes farther from the ninth major surface to become continuous with the sixth major surface with proximity to the fifth major surface includes a plane, and
a portion where the fourteenth major surface becomes farther from the thirteenth major surface to become continuous with the twelfth major surface with proximity to the eleventh major surface includes a plane.

14. The power semiconductor device according to claim 8, wherein the first semiconductor chip and the second semiconductor chip are IGBTs.

15. An inverter device comprising:
the power semiconductor device according to claim 1;
a direct-current power source;
a capacitor; and
an output terminal,
the first conductor of the power semiconductor device being electrically connected to a positive voltage side of the direct-current power source,
the second conductor of the power semiconductor device being electrically connected to the output terminal,
the capacitor being electrically connected in parallel to the direct-current power source.

16. An inverter device comprising:
the power semiconductor device according to claim 8;
a direct-current power source;
a capacitor; and
an output terminal,
the first conductor of the power semiconductor device being electrically connected to a positive voltage side of the direct-current power source,
the second conductor of the power semiconductor device being electrically connected to the output terminal,
the third conductor of the power semiconductor device being electrically connected to a negative voltage side of the direct-current power source,
the capacitor being electrically connected in parallel to the direct-current power source.
